(19) United States
(12) Patent Application Publication
(10) Pub. No.: US 2007/0205495 A1
(43) Pub. Date: Sep. 6, 2007

(54) Electronic Component With Stacked Semiconductor Chips And Heat Dissipating Means

(76) Inventors: Elstan Anthony Fernandez, Singapore (SG); Seah Lee Hua, Singapore (SG)

Correspondence Address: BAKER BOTTS, L.L.P., 98 SAN JACINTO BLVD., SUITE 1500, AUSTIN, TX, 78701-4039, US

(21) Appl. No.: 11/670,821

(22) Filed: Feb. 2, 2007

Related U.S. Application Data
(63) Continuation of application No. PCT/IB04/02447, filed on Aug. 2, 2004.

(51) Int. Cl. H01L 23/02

(52) U.S. Cl. 257/686

(57) ABSTRACT

Electronic component (1; 20) has at least one stack (2; 21, 23) with at least two semiconductor chips (8, 9; 32, 33; 42, 43). Each semiconductor chip (8, 9; 32, 33; 42, 43) includes an active surface including integrated circuits (11; 35) and chip contact pads (10; 34) at least one being a ground cell (13; 37) and a passive surface. The electronic component (1; 20) further includes at least one intermediate spacer (14; 38; 44) with a thermally conductive and electrically conductive material. The intermediate spacer block (14; 38; 44) is positioned between the active surface of a semiconductor chip (9; 33; 43) and the passive surface of an adjacent semiconductor chip (8; 32; 42) in the stack (2; 21, 23). The intermediate spacer (14; 38; 44) and the ground cells (13; 37) of the semiconductor chips (9; 33; 43) are electrically connected and have a common ground.

### CROSS-REFERENCE TO RELATED APPLICATION

This application is a continuation of co-pending International Application No. PCT/IB2004/002447 filed Aug. 2, 2004, which designates the United States.

### TECHNICAL FIELD

The invention relates to an electronic component which includes at least two stacked semiconductor chips and a means for dissipating heat.

### BACKGROUND

The demands of increased chip functionality in combination with the requirement to reduce the size and weight of semiconductor packages leads to a negative impact on the electrical performance of the package due to poor heat dissipation. Poor heat dissipation from the package results in problems such as crosstalk noise, signal interference and signal distortion.

One approach to improving heat dissipation from semiconductor packages is by improved selection of the materials of the package, for instance using die attach material and substrate material with a higher thermal conductivity or a lighter-weight material, such as a metal matrix composite, for the heat spreader as disclosed in U.S. Pat. No. 6,250,127. However, this approach leads to increased costs and an increased complexity of the assembly process as specialized assembly methods are introduced into the assembly line.

### SUMMARY

An electronic component according to an embodiment may comprise at least one stack which includes at least two semiconductor chips. Each semiconductor chip includes an active surface with integrated circuits and chip contact pads, at least one being a ground cell. The stack further includes an intermediate spacer block comprising a thermally conductive and electrically conductive material. The intermediate spacer block is positioned between the active surface of a semiconductor chip and the passive surface of an adjacent semiconductor chip in the stack. The intermediate spacer and the ground cells of the semiconductor chips are electrically connected and have a common ground.

### BRIEF DESCRIPTION OF THE DRAWINGS

An embodiment of the invention will now be described by way of example with reference to the drawings.

FIG. 1 shows an electronic component according to an embodiment including two stacked semiconductor chips, and

FIG. 2 shows an electronic component according to an embodiment including two stacks of wire-bonded semiconductor chips and a means of dissipating heat.

### DETAILED DESCRIPTION

The electronic component according to an embodiment provides a more reliable semiconductor package as the intermediate spacer block between the semiconductor chips of the stack provides shielding between the adjacent chips while at the same time providing a means for dissipating heat throughout the stack. This avoids hot spots within the stack as heat is more evenly distributed throughout the stack. The common ground also reduces signal interference and signal noise.

The electronic component also may include external contacts, according to an embodiment, such as solder balls which enable the component to be mounted on and electrically connected to a substrate such as a printed circuit board.

According to an embodiment, the intermediate spacer block can be attached to the active surface of the semiconductor with electrically conductive adhesive means. This provides the electrical connection and grounding of the intermediate spacer with the ground cell of the semiconductor chip in addition to a good mechanical connection between the semiconductor chip and the intermediate spacer block. This leads to a mechanically stable stack.

According to an embodiment, the ground and power cells can be positioned towards the lateral centre of the active surface of the semiconductor chip. This improves the heat dissipation from the semiconductor chip as the heat generated by the integrated circuits is more directly conducted into the intermediate spacer block and, therefore, more effectively and evenly distributed throughout the stack. More preferably, the ground and power cells are located in approximately the centre of the active surface of the chip.

According to an embodiment, the semiconductor chip of the stack can be electrically connected to the substrate and to each other by bond wires. Alternatively, the semiconductor chips are electrically connected to the substrate by flip-chip contacts. The common ground is preferably provided by bond wires.

According to an embodiment, the electronic component may further include a substrate including a plurality of inner contact pads and conductive traces, electrically conductive vias and a plurality of external contact areas. The substrate can preferably be a multi-layer substrate. The substrate may provide mechanical support for the stack and a re-wiring structure between the chip contact pads and the external contact areas of the substrate.

According to an embodiment, the stack can be preferably mounted on the substrate by the rear surface of the lower semiconductor chip of the stack. Heat generated by the active surfaces of the semiconductor chips can be more effectively dissipated upwardly away from the substrate. According to an embodiment, conventional die attach materials can be preferably used to attach the semiconductor chip to the substrate.

The electronic component according to an embodiment, may include two stacks of semiconductor chips. A first stack is mounted on one surface of the substrate by the rear surface of the lower semiconductor chip of the first stack. A second stack is mounted on the opposing surface of the substrate by the rear surface of the lower semiconductor chip of the second stack. This arrangement advantageously increases the number of semiconductor chips in the electronic component while reducing the length of the electrical connections between the chips and the substrate. This reduces the problems associated with the inductance of the electrical connections, such as bond wires.

According to an embodiment, the substrate may include an opening and a centre spacer block, the centre spacer block being positioned in the opening and attached to the passive rear surface of the lower semiconductor chip of the first stack and the passive rear surface of the lower semiconductor chip of the second stack.

According to an embodiment, the opening in the substrate can, preferably, be laterally smaller at least in one portion than the lateral dimensions of the lower semiconductor chips of the stacks. This enables the lower semiconductor chip and therefore the stack to be attached to the substrate in addition to the centre spacer block. This improves the stability of the two stacks.

According to an embodiment, the centre spacer block may, preferably, comprise an electrically and thermally conductive material and, more preferably, may comprise essentially the same material as the intermediate spacer blocks. The centre spacer block provides shielding between the semiconductor chips of the first and second stack and enables heat to be distributed throughout the first and second stacks. Heat distribution from hot spots and, therefore, the thermal performance of the electronic component is improved.

According to an embodiment, the electronic component further may include at least one heat dissipating means. This further improves heat dissipation from the electronic component.

According to an embodiment, the electronic component, preferably, may further include a first outer spacer block positioned on the active surface of the upper semiconductor chip of the first stack and a first heat dissipating means attached to the first outer spacer block. The first outer spacer block may, according to an embodiment, be attached to the active surface of the upper semiconductor chip of the stack by electrically adhesive means. The first outer spacer block is then electrically connected to the ground cells of the upper semiconductor chip and, therefore, electrically connected with the intermediate spacer blocks of the stack and to the common ground.

According to an embodiment, the outer spacer block also may provide a heat dissipating path from the active surface of the upper chip in addition to the stack. The first heat dissipating means such as a plate or cap can, according to an embodiment, be preferably attached to the first outer spacer block with thermally conductive adhesive so improve the heat dissipation from the stack to the heat dissipating plate. The adhesive may also be electrically conductive. According to an embodiment, the heat dissipating plate may comprise the outer surface of the electronic component. This improves the dissipation of the heat from the electronic component into the surrounding environment.

The outer spacer block also improves the ease with which the heat dissipating means, such as the plate, is attached to the stack. According to an embodiment, the stack can be assembled and wire-bonded to the substrate and the common ground provided. The heat dissipation plate may then be attached to the outer surface of the stack provided by the outer spacer block.

According to an embodiment, the electronic component further may include a second outer spacer block positioned on the active surface of the outer semiconductor chip of the second stack and a second heat dissipating means attached to the second outer block.

This configuration is advantageous as a heat dissipating means is included on both the upper and lower surfaces of the component. Heat dissipation from the package is, therefore, improved. The second heat dissipating means may comprise a flat plate or, more preferably, a cap which encloses the second stack.

According to an embodiment, the lower surface of the substrate onto which the second stack is attached, preferably, also includes the external contact areas of the component. These can be preferably positioned towards the edges of the substrate. According to an embodiment, the second stack and second heat dissipating means may be preferably laterally smaller than the lateral space provided within the external contact areas.

According to an embodiment, the height of the stack including the attached heat dissipating means may also, preferably, be less than the height of the external contacts of the component. This enables the component to be mounted on the printed circuit board by the external contacts.

According to an embodiment, the centre, intermediate and outer spacer blocks and the first and second heat dissipating means may comprise a metal matrix composite.

A metal matrix composite is advantageous as a large range of thermal conductivities, thermal expansion coefficients, electrical resistivities can be provided in addition to low density, high strength and high stiffness by appropriate choice of the metal matrix composite and its composition. Therefore, the heat dissipation is further improved and thermal expansion coefficients more effectively matched between the chip and the heat dissipating means improving both the thermal conduction and also reliability of the component. Since, the density of metal matrix composites is less than that of metal the weight and size of the component can also be reduced. More preferably, according to an embodiment, the material comprising the spacer block may have a negative thermal expansion coefficient, further improving reliability of the package as the possibility of delamination of the plastic housing from the semiconductor chip is further reduced.

According to an embodiment, the centre, intermediate and outer spacer blocks can be, preferably, laterally approximately the same size, and can be, preferably, laterally smaller than semiconductor chips and are laterally positioned approximately centrally semiconductor chips of the stack. This improves the flexibility of the stacking process and reduces manufacturing costs. This also leads to a mechanically stable stack.

According to an embodiment, the upper semiconductor chip of the stack can be, preferably, laterally smaller than the lower adjacent semiconductor chip. According to some embodiments, the semiconductor chips can be progressively laterally smaller in the upwards direction of the stack. This configuration enables the bonding process to more easily take place after the stack has been assembled. This is advantageous as the manufacturing steps are simplified in that a plurality of stacks can be produced, then attached to a plurality of substrates in one manufacturing step and the bonding of a plurality of substrates can be carried out in one manufacturing step. According to an embodiment, the semiconductor chips of one stack, preferably, electrically may be connected to each other. The semiconductor chips of one stack may also be electrically connected to the semiconductor chips of a second stack, providing the stacks with a common ground or common electrical connections.

According to an embodiment, the first heat dissipating means can be a plate and the second heat dissipating means can be a cap, which is, more preferably, further attached to the substrate. The first heat dissipating means, according to an embodiment preferably, may have similar lateral dimensions to the substrate or the electronic component or the largest semiconductor chip of the stack. This maximises the available surface area from which heat is dissipated while not increasing the size of the component. The surface area of second heat dissipating means is increased through the use of a cap structure. According to an embodiment, the second heat dissipating means can, preferably, be laterally smaller than the first heat dissipating means so that it is accommodated in the area of the substrate within the external contacts of the component.

A heat dissipation means in the form of a cap which is attached to the substrate by its rim is also advantageous as it provides a container for the plastic encapsulation material if the stack is to be encapsulated. In this case, according to an embodiment, an opening in the substrate can be provided and the encapsulation material provided from the upper surface, flowing into the cap attached to the bottom surface of the substrate. The cap prevents leakage of the encapsulant onto the external contact areas of the substrate.

According to yet another embodiment, a method to assemble an electronic component may comprise the following steps. At least two semiconductor chips, each including an active upper surface including integrated circuits and contact pads at least one of which is a ground cell. At least one intermediate spacer block comprising a thermally conductive and electrically conductive material is also provided.

According to an embodiment, at least one stack of semiconductor chips can be assembled by attaching an intermediate spacer to the active surface of a semiconductor chip. The passive surface of a second semiconductor chip can be attached to the intermediate spacer block, preferably with adhesive means. Preferably, the intermediate spacer block can be attached to the active surface of the semiconductor chip and the ground cells of the chip by electrically conductive adhesive means, thereby electrically connecting at least one ground cell with the adjoining intermediate spacer.

According to an embodiment, the intermediate spacer block and the ground cells of the semiconductor chips can then be electrically connected and a common ground can be provided.

The method according to an embodiment preferably may include the further steps of providing a substrate including a plurality of inner contact pads and conductive traces, electrically conductive vias and a plurality of external contact areas. A first stack of semiconductor chips can then be attached to the substrate by the rear surface of the lower semiconductor chip.

This method has the advantage that a number of stacks of semiconductor chips can be made in one manufacturing step. One or more stacks are then attached to each substrate in a separate manufacturing step. Alternatively, one or more stacks are assembled on each substrate. A semiconductor chip is attached to the substrate, an intermediate spacer block is attached to the first semiconductor chip and a second semiconductor chip is mounted onto the intermediate spacer block to build up the desired number of chips in the stack.

The method according to an embodiment, preferably, may include the further steps of attaching a first outer spacer block to the active surface of the upper semiconductor chip of the first stack, preferably, by electrically conductive adhesive means and attaching a first heat dissipating means to the first outer block, preferably by adhesive means.

According to an embodiment, a second outer spacer block can be attached to the active surface of the upper semiconductor chip of the second stack, preferably, by electrically conductive adhesive means and attaching a second heat dissipating means to the second outer block, preferably by adhesive means.

According to an embodiment, the outer spacer block and heat spreading means can be, preferably, mounted on the upper semiconductor chip of the stack during the first manufacturing step and a stack including the heat spreading means is attached to the substrate. This method has the advantage that the manufacturing process is simplified as the stack is assembled in one step. Alternatively, the outer spacer block or the heat spreading means is attached to the stack after the stack has been attached to the substrate. This has the advantage that the bonding between the upper semiconductor chip and the substrate is more easily carried out before the heat spreading means is attached.

The electronic component according to an embodiment, such as a ball grid array application, may provide a spacer block for a stacked chip configuration which acts as part of the heat dissipation system of the component and shields adjacent semiconductor chips. The heat generating components of the chip, such as the ground or power cells, are also positioned in the centre o the active surface. Since the spacers are attached to the active area of the chip, heat dissipation is improved. The heat dissipating system, including the centre, intermediate and outer spacer blocks and the first and second heat dissipating means is laterally aligned within the package providing a mechanical stable package in addition to improved heat dissipation. The heat dissipation means such as the upper plate and lower cap also comprise the outer surfaces of the package which further improves heat dissipation.

The spacer blocks of the stack according to an embodiment may comprise an electrically conductive material, preferably a metal matrix composite, so that the spacers also provide electrical shielding between the adjacent semiconductor chips of the stack. The spacers also provide space above the active surface of the chips which enable bond wires to extend between the chip and the substrate without the bond wires being in contact with the adjacent chips.

According to an embodiment, the outer spacer blocks may provide a means by which the heat dissipating means is easily attached to the stack and enable the heat dissipating means to be attached to the stack above the bond wires so that the bond wires between the chip and the substrate and/or other chips in the stack are not damaged.

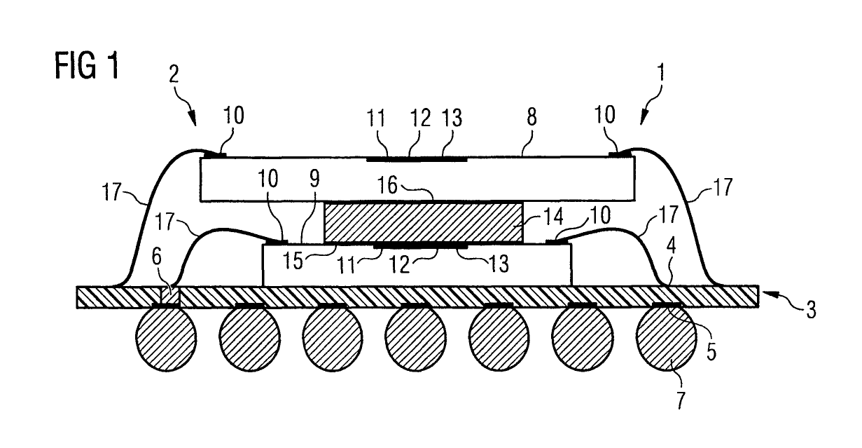

FIG. 1 shows an electronic component 1 which includes a stack 2 including two semiconductor chips attached to a substrate 3.

The substrate 3 includes a plurality of inner contact pads 4 on its upper surface and a plurality of external contact pads 5 on its lower surface. Conductive vias 6 connect the inner contact pads 4 with external contact pads 5 on the lower surface of the substrate 3. A solder ball 7 is attached to each of the external contact pads 5 to form the electrical connection between the electronic component 1 and an external substrate such as a printed circuit board which is not shown in the diagram.

The stack 2 includes a first upper semiconductor chip 8 and a second lower semiconductor chip 9. The passive surface of the second semiconductor chip 9 of the stack 2 is mounted on the upper surface of the substrate 3.

Each semiconductor chip 8, 9 includes an active surface which includes chip contact pads 10 located towards the outer edges of the chip and a passive rear surface. The active surface of each semiconductor chip 8, 9 further includes integrated circuits 11 and, according to an embodiment, power 12 and ground cells 13 which are located towards the lateral centre of the active surface of each semiconductor chip 8, 9.

An intermediate spacer block 14, which comprises a metal matrix composite, is positioned on the active surface in approximately the lateral centre of the second lower semiconductor chip 9. It is attached to the active surface of the chip with an electrically conductive adhesive layer 15. The intermediate spacer block 14 is, therefore, positioned on the integrated circuits 11, power cells 12 and ground cells 13 on the active surface of the second lower semiconductor chip 9.

The ground signal cells 13 are positioned on the active surface of the chip 8 so that they align with the adjoining spacer block 14. The intermediate spacer block 14 is electrically connected by the electrically conductive adhesive 15 to the ground cells 12 of the second lower semiconductor chip 9.

The first upper semiconductor chip 8 is laterally larger than the second lower semiconductor chip 9. The semiconductor chip 8 is laterally positioned so that its lateral centre is approximately laterally aligned with the centre of the first intermediate spacer block 14. The passive rear surface of the semiconductor chip 8 is mounted by a second adhesive layer 16 to the upper surface of the first intermediate spacer block 14 which is also attached to the active surface of the second semiconductor chip 9.

The semiconductor chips 8, 9 are electrically connected by a plurality of bond wires 17 between the chip contact pads 10 and inner contact areas 5, located on the upper surface of the substrate 3. Semiconductor chip 8 is electrically connected by a second plurality of bond wires 18 to the semiconductor chip 13.

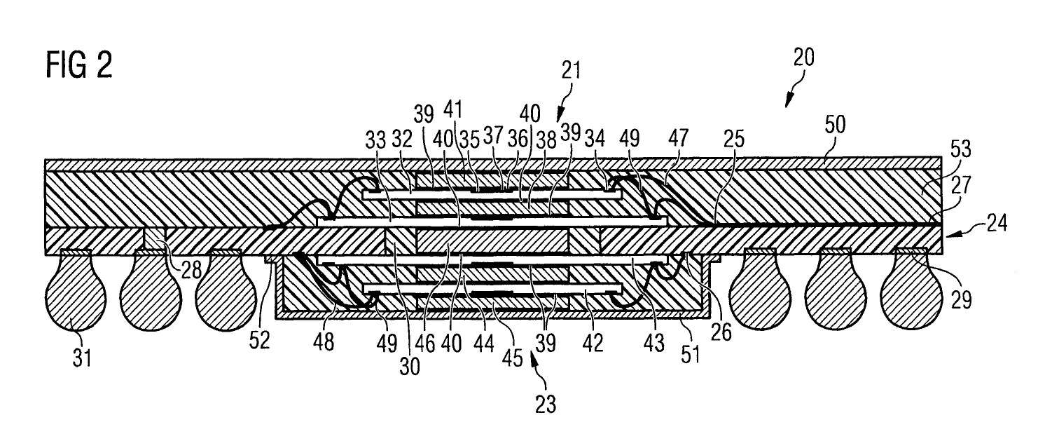

FIG. 2 shows an electronic component 20 which includes a first stack 21 including two semiconductor chips and a second stack 23 including two semiconductor chips attached to a substrate 24.

The multi-layer substrate 24 includes a plurality of inner contact pads 25 on its upper surface and a plurality of contact pads 26 on its lower surface, and conductive traces 27 in addition to vias 28. The conductive traces 27 and vias 28 connect the inner contact pads 25, 26 with external contact areas 29 on the lower surface of the substrate 24. The substrate 24 further includes an opening 30 positioned approximately in its lateral centre. In the embodiment shown in FIG. 2, a solder ball 31 is attached to each of the external contact areas 29 to form the electrical connection between the electronic component 20 and an external substrate such as a printed circuit board which is not shown in the diagram.

The first stack 21 includes a first upper semiconductor chip 32 and a second lower semiconductor chip 33. Each semiconductor chip 32, 33 includes an active surface which includes chip contact pads 34 located towards the outer edges of the chip and a passive rear surface. The active surface of each semiconductor chip 32, 33 further includes integrated circuits 35 and, according to an embodiment, power 36 and ground cells 37 which are located towards the lateral centre of each semiconductor chip 32, 33.

An intermediate spacer block 38 which comprises a metal matrix composite is positioned on the active surface in approximately the lateral centre of the second lower semiconductor chip 33. It is attached to the active surface of the chip with an electrically conductive adhesive layer 39. The intermediate spacer block 38 is, therefore, positioned on the integrated circuits 35, power cells 35 and ground cells 36 on the active surface of the second lower semiconductor chip 33.

The ground signal cells 37 are positioned on the active surface of the chips 32, 33 so that they align with the adjoining spacer block 38 of the stack 21, 23. The intermediate spacer block 38 is electrically connected by the electrically conductive adhesive 39 to the ground cells 37 of the second lower semiconductor chip 33.

The first upper semiconductor chip 32 also includes an active surface with chip pads 34 laterally positioned towards the edges of the chip and integrated circuits 35, power cells 36 and ground cells 37 which are laterally located towards the centre. The first upper semiconductor chip 32 is laterally smaller than the second lower semiconductor chip 33. The semiconductor chip 32 is laterally positioned so that its lateral centre is approximately laterally aligned with the centre of the first intermediate spacer block 38. The passive rear surface of the semiconductor chip 32 is mounted by a second adhesive layer 40 to the upper surface of the first intermediate spacer block 38 which is also attached to the active surface of the second semiconductor chip 33.

A first outer spacer block 41 is mounted on the upper active surface of the semiconductor chip 32 by an adhesive layer 39. The first outer spacer block 41 has approximately the same outer dimensions and is laterally aligned with the intermediate spacer block 38. The first outer spacer block 41 is, therefore, positioned over the integrated circuits 35, power cells 36 and ground cells 37 on the active surface of the chip 32 but does not cover the chip contact pads 33. The first outer spacer block 41 also comprises a metal matrix composite.

The passive surface of the second semiconductor chip 33 of the stack 21 is mounted on the upper surface of the substrate 24 so that its lateral centre is positioned approximately over the lateral centre of the opening 30 of the substrate 24. The semiconductor chip 33 is laterally larger than the opening 30 and is attached to the upper surface of the substrate 24 only towards its outer edges.

The electronic component includes a second stack 23 including two semiconductor chips 42 and 43 attached to the lower surface of the substrate 24.

The second stack 23 is essentially the same as the first stack 21. The second stack 23 comprises a first semiconductor chip 42, a second semiconductor chip 43 and an intermediate spacer block 44 positioned between the first 42 and second 43 semiconductor chips so that it is attached to the active surface of the second semiconductor chip 43 and passive rear surface of the first semiconductor chip 42. A second outer spacer block 45 is attached to the active surface of the first semiconductor chip 42.

The passive rear side of the semiconductor chip 43 of the second stack 23 is mounted on the bottom surface of the substrate 24. Semiconductor chips 42 and 43 have approximately the same lateral dimensions as semiconductor chips 32 and 33 respectively. The stack 23 is also arranged so that the lateral centre of each member is approximately laterally aligned and the stack laterally positioned so that its lateral centre is approximately laterally aligned with the lateral centre of the opening 30. The semiconductor chip 43 is attached only in its edge regions to the substrate 24 using conventional die attach material.

A centre spacer block 46 is positioned approximately centrally in the opening 30 between the rear passive surfaces of the semiconductor chips 33 and 43. The centre spacer block 46 is laterally smaller than the lateral dimensions of the opening 30 and has a height which is approximately the same as the height of the substrate 24. The centre spacer block 46 is connected via adhesive 40 to the rear surface of the semiconductor chips 33 and 33. The centre spacer block 46 comprises a metal matrix composite.

The intermediate spacer blocks 38, 44 and outer spacer blocks 41, 45 have approximately the same lateral dimensions as the centre spacer block 46. The height of the intermediate spacer blocks 38, 44 and outer spacer blocks 41, 45 is slightly smaller than that of the centre spacer block 46.

The semiconductor chips 32, 33, 42 and 43 are electrically connected by a plurality of bond wires 47 between the chip contact pads 34 and inner contact areas 25, 26 located on the upper and lower surfaces of the substrate 24, respectively. Semiconductor chip 32 is electrically connected a second plurality of bond wires 48 to the semiconductor chip 33. Similarly, semiconductor chips 42 and 43 of the second stack 23 are electrically connected by bond wires 49.

The electronic component 20 further includes a heat dissipating plate 50 which is mounted by adhesive 49 to the first outer spacer block 41 positioned on the semiconductor chip 32. The heat dissipating plate 50 has approximately the same lateral dimensions as the substrate 24 and the outer upper surface of the heat dissipating plate 50 forms the outer upper surface of the electronic component 20.

The electronic component 20 includes a heat dissipating cap 51 which encloses the second stack 23 mounted on the bottom surface of the substrate 24. The heat dissipating cap 51 is also mounted on the bottom surface of the substrate 24 by its rim 52. The rim 52 has an L-shaped cross-section so that the rim 52 protrudes outwards increasing the surface area of the bottom surface of the cap 51 and improving the reliability of the mounting of the cap 51 to the substrate 24.

The heat dissipating cap 51 has dimensions so that it laterally fits between the solder balls 31 which form the external contacts of the electronic component 20 and has a height which is slightly smaller than the height of the solder balls 31. The electronic component 20 can therefore be mounted on an external substrate such as a printed circuit board without the heat spreading cap 51 being in contact with the external substrate.

The electronic component 20 further includes a plastic encapsulation medium 53 which encapsulates the semiconductor chips 32, 33, 42, 43, bond wires 47, 48, 49, centre spacer block 46, intermediate spacer blocks 38, 44 and outer spacer blocks 41, 45 and the opening 30 in a single mass. The encapsulation medium 53 fills the volume of the electronic component 20 between the heat dissipating cap 51 and heat spreading plate 50.

The centre spacer block 46, intermediate spacer blocks 38, 44 and outer spacer blocks 41, 45 enable heat to be efficiently dissipated from the stacks 22, 23 as they are mounted on the active area of the active, heat generating surfaces of the semiconductor chips 32, 33, 42, 43. Two further heat dissipating means, the plate 50 and cap 51, are attached to the stacks 21 and 23 respectively enabling heat to be dissipated both upwardly and downwardly from the electronic component 20.

The intermediate spacer blocks 38 and 44 and outer spacer blocks 41, 45 provide shielding between adjacent semiconductor chips 32, 33 and 42, 43. Since the intermediate 38, 44 and outer 41, 45 spacer blocks are electrically connected to the ground cells 37 of the respective adjacent active chip surface 32, 33, 42, 43 by electrically conductive adhesive 39, and the ground cells 37 of the semiconductor chips 32, 33 of the stack 21 and semiconductor chips 42, 43 of the stack 23 are electrically connected a common ground for each stack 21, 23 is provided.

### Reference numbers

1 electronic component
2 stack
3 substrate
4 inner contact pad
5 external contact pad
6 via
7 solder ball
8 first upper semiconductor chip
9 second lower semiconductor chip
10 chip contact pads
11 integrated circuits
12 power cell
13 ground cell
14 intermediate spacer block
15 electrically conductive adhesive
16 second adhesive layer
17 bond wire
18 bond wire
20 electronic component
21 first stack
23 second stack
24 substrate
25 upper inner contact pad
26 lower inner contacts pad
27 conductive trace
28 via
29 external contact pad
30 opening
31 solder ball
32 first semiconductor chip
33 second semiconductor chip
34 chip contact pads
35 integrated circuit
36 power cell
37 ground cell
38 intermediate spacer block
39 electrically conductive adhesive layer
30 adhesive layer
41 first outer block
42 first semiconductor chip
43 second semiconductor chip
44 intermediate spacer
45 second outer spacer block
46 centre spacer block
47 first bond wire
48 second bond wire
49 third bond wire
50 heat dissipation plate
51 heat dissipation cap
52 rim of heat dissipation cap
53 encapsulation material

What is claimed is:

1. An electronic component comprising:
at least one stack comprising at least two semiconductor chips, each semiconductor chip comprising an active surface comprising integrated circuits and chip contact pads at least one being a ground cell and a passive surface,
at least one intermediate spacer comprising a thermally conductive and electrically conductive material, the intermediate spacer block being positioned between the active surface of a semiconductor chip and the passive surface of an adjacent semiconductor chip in the stack,
wherein the intermediate spacer and the ground cells of the semiconductor chips are electrically connected and have a common ground.

2. The electronic component according to claim 1, wherein at least one intermediate spacer block is attached to the semiconductor chips with electrically conductive adhesive means.

3. The electronic component according to claim 1, wherein the ground cells are positioned towards the lateral centre of the active surface of the semiconductor chip.

4. The electronic component according to claim 1, wherein the electronic component further includes a substrate comprising a plurality of inner contact pads and conductive traces, electrically conductive vias, and a plurality of external contact areas, the stack being mounted on the substrate by the rear surface of the lower semiconductor chip.

5. The electronic component according to claim 1, wherein the electronic component further comprises at least one heat dissipating means.

6. The electronic component according to claim 1, wherein the electronic component further comprises a first outer spacer block positioned on the active surface of the upper semiconductor chip of the first stack and a first heat dissipating means attached to the first outer spacer block.

7. The electronic component according to claim 1, wherein a first stack is mounted on one surface of the substrate by the rear surface of the lower semiconductor chip and a second stack is mounted on the opposing surface of the substrate by the rear surface of the lower semiconductor chip.

8. The electronic component according to claim 1, wherein the second stack includes a second outer spacer block positioned on the active surface of the upper semiconductor chip and a second heat dissipating means attached to the second outer block.

9. The electronic component according to claim 1, wherein the substrate comprises an opening and a centre spacer block, the centre spacer block being positioned in the opening and attached to the lower semiconductor chip of the first stack and the lower semiconductor chip of the second stack.

10. The electronic component according to claim 1, wherein the centre, intermediate and outer spacer blocks and the heat dissipating means comprise a metal matrix composite.

11. The electronic component according to claim 1, wherein the centre, intermediate and outer spacer blocks are laterally approximately the same size, are laterally smaller than the semiconductor chips and are laterally positioned approximately centrally on semiconductor chips.

12. The electronic component according to claim 1, wherein the upper semiconductor chip is laterally smaller than the lower semiconductor chip of the stack.

13. The electronic component according to claim 1, wherein the first heat dissipating means is a plate and the second heat dissipating means is a cap.

14. A method to assemble an electronic component comprising the following steps:
providing at least two semiconductor chips, each including an active upper surface including integrated circuits and contact pads at least one of which is a ground cell,
providing at least one intermediate spacer block comprising a thermally conductive and electrically conductive material,
assembling at least one stack of semiconductor chips by attaching an intermediate spacer on the active surface of a semiconductor chip, and attaching the passive surface of an adjacent semiconductor chip on the intermediate spacer block, and
electrically connecting the intermediate spacer block and the ground cells of the semiconductor chips and providing a common ground.

15. The method according to claim 14, comprising the following further steps:
providing a substrate including a plurality of inner contact pads and conductive traces, electrically conductive vias, and a plurality of external contact areas, and
attaching at least one stack of semiconductor chips to the substrate by the rear surface of the lower semiconductor chip.

16. The method according to claim 14, comprising the following further steps:
attaching a first outer spacer block to the active surface of the upper semiconductor chip of the first stack, and
attaching a first heat dissipating means to the first outer block.

17. The method according to claim 14, further comprising the following steps:
attaching a second outer spacer block to the active surface of the upper semiconductor chip of the second stack, and
attaching a second heat dissipating means to the second outer block.

18. A electronic component comprising:
a first and second semiconductor chip, each semiconductor chip comprising an active surface comprising integrated circuits and chip contact pads at least one being a ground cell and a passive surface,
at least one spacer comprising a thermally conductive and electrically conductive material, and being arranged between the active surface of the first semiconductor chip and the passive surface of the second semiconductor chip,
wherein the intermediate spacer and the ground cells of the first and second semiconductor chips are electrically connected and have a common ground.

19. The electronic component according to claim 18, wherein at least one intermediate spacer block is attached to the first and second semiconductor chips with electrically conductive adhesive means.

20. The electronic component according to claim 18, wherein the electronic component further includes a substrate comprising a plurality of inner contact pads and conductive traces, electrically conductive vias, and a plurality of external contact areas, the second semiconductor chip being mounted on the substrate by the rear surface.
